(19) United States
(12) Patent Application Publication
(10) Pub. No.: US 2008/0130388 A1
(43) Pub. Date: Jun. 5, 2008

(54) SEMICONDUCTOR DEVICE HAVING A SYSTEM IN PACKAGE STRUCTURE AND METHOD OF TESTING THE SAME

(75) Inventor: Kenichiro Mimoto, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/951,268

(22) Filed: Dec. 5, 2007

(30) Foreign Application Priority Data
Dec. 5, 2006 (JP) 2006-328586

(51) Int. Cl. G01R 31/26; G11C 7/00

(52) U.S. Cl. 365/201; 324/765

(57) ABSTRACT

A memory chip and an integrated circuit chip are electrically connected via a plurality of bonding wires, and thereby, a semiconductor device is assembled as a SIP product. A test circuit required for testing the memory chip is built in the memory chip only, and the integrated circuit chip is not provided with the test circuit.

### CROSS-REFERENCE TO RELATED APPLICATIONS

This application is based upon and claims the benefit of priority from prior Japanese Patent Application No. 2006-328586, filed Dec. 5, 2006, the entire contents of which are incorporated herein by reference.

### BACKGROUND OF THE INVENTION

1. Field of the Invention

The present invention relates to a semiconductor device. In particular, the present invention relates to a test circuit of a semiconductor device having a system in package (SIP) providing a plurality of semiconductor chips mutually connected in the same package, and to a test method. For example, the present invention is applicable to SIP products including a memory chip and a logic chip.

2. Description of the Related Art

Conventionally, SIP products stacking a memory chip and other integrated circuit chips have been known. For example, a SIP product combining general memory chip such as a DRAM and logic chip usually has the following structure. According to the structure, the memory chip is stacked on the center portion of a logic chip, and both chips are connected using bonding wires. In such a SIP product, the general memory chip usually has a small data bit width, and forms all terminals (pins) required for testing the memory chip as a pad. Therefore, when the memory chip is tested, a memory normal function test is made. However, if the data bit width of the general memory chip is increased to improve the data transfer rate, the following problem arises. Specifically, if all pins required for the test are formed as a pad, the chip size increases or it is impossible to make a test using a tester. In such a case, there is a need of providing a self-test circuit in the memory chip like a memory test of a conventional system-on-chip (SoC) type memory embedded chip. On the other hand, the logic chip needs to include the following test circuit. The test circuit is provided to make access test with respect to the memory chip after SIP products are assembled, for example, operation speed test and module burn-in.

According to the design of the SIP products having the general memory chip including many data bits, both memory chip and logic chip must include a test circuit used for memory chip test. In other words, this means that the logic chip must includes an inherently unnecessary test circuit for the general memory chip.

However, if the test circuit built in both memory chip and logic chip, it is possible to make a test of the memory chip. But, if failure occurs, it is difficult to determine whether the failure occurs in the memory chip or in an I/O cell between the memory chip and the logic chip and/or in bonding wires.

In order to solve the foregoing problem, conventionally, a scan circuit is built in both memory chip and logic chip. The scan circuit makes a scan test with respect to a plurality of I/O cells included in each of a multi-bit memory chip and logic chip. However, in this case, the operation of the I/O cells is confirmed in each chip, but a connection test between chips is not made via bonding wires. For this reason, it is impossible to detect the failure of the bonding wires after SIP products are assembled.

Even if the logic chip is configured so that failure is detected in I/O cells of both chips and/or bonding wires, the following problem arises. Specifically, if a bonding wire failure redundancy circuit is not provided corresponding to the failure of the bonding wires, the failure of the bonding wires is not redundant.

Jpn. Pat. Appln. KOKAI publication No. 2005-300485 discloses the following semiconductor device. The semiconductor device has the following configuration. According to the configuration, an ASIC (system) chip and an SDRAM (memory) chip are included in a single package, and an SDRAMBIST used for testing the memory chip is formed in a system chip.

### BRIEF SUMMARY OF THE INVENTION

According to a first aspect of the present invention, there is provided a semiconductor device having a system in package structure, comprising:

a memory chip having a memory circuit, and

including a test circuit for making an operation test of the memory chip itself; and

an integrated circuit chip electrically connected with the memory chip.

According to a second aspect of the present invention, there is provided a method of testing a semiconductor device assembled as a system in package product including a memory chip and an integrated circuit chip each having a plurality of input/output cells, which are electrically connected via a plurality of bonding wires, comprising:

making a test of the memory chip to make a detection whether or not failure exists in each input/output cell of the memory chip and the integrated circuit chip and/or the plurality of bonding wires.

According to a third aspect of the present invention, there is provided a method of testing a semiconductor device assembled as a system in package product including a memory chip and an integrated circuit chip each having a plurality of input/output cells,

the plurality of input/output cells including a plurality of normal input/output cells and a plurality of spare input/output cells, and

the plurality of bonding wires including a plurality of normal bonding wires and a plurality of spare bonding wires mutually connecting the spare input/output cells, comprising:

making a test of the memory chip to make a detection whether or not failure exists in each input/output cell of the memory chip and the integrated circuit chip and/or the plurality of bonding wires; and

shifting a connection path in replacement with the spare bonding wire and the spare input/output cell to make failure redundancy of the input/output cell and/or the bonding wire when failure is detected in any of the input/output cell on each chip or the bonding wire according to the test.

### BRIEF DESCRIPTION OF THE SEVERAL VIEWS OF THE DRAWING

FIG. 1 is a block diagram schematically showing the configuration of a semiconductor device according to a first embodiment;

FIG. 2 is a perspective view showing a memory chip and a logic chip shown in the semiconductor device of FIG. 1;

FIG. 3 is a block diagram schematically showing the configuration of a semiconductor device according to a second embodiment; and

FIG. 4 is a block diagram schematically showing the configuration of a semiconductor device according to a third embodiment.

### DETAILED DESCRIPTION OF THE INVENTION

Various embodiments of the present invention will be hereinafter described with reference to the accompanying drawings. In the following description, the same reference numbers are used to designate common portions all over the drawings.

### First Embodiment

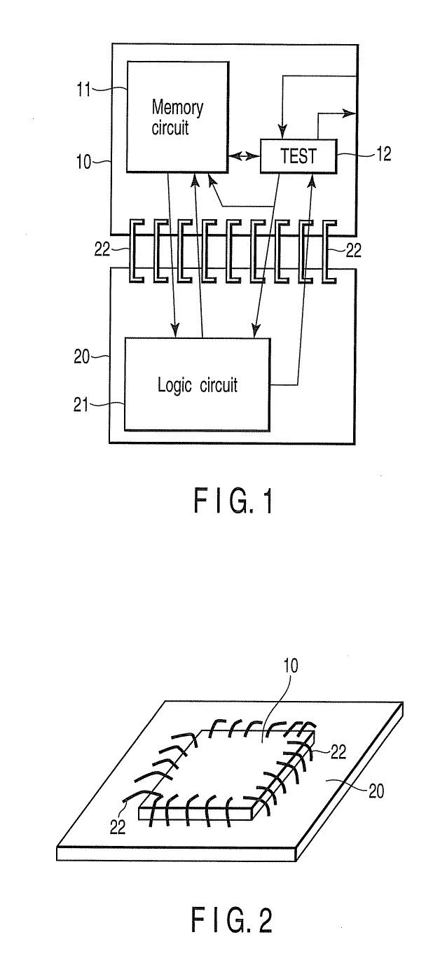

FIG. 1 is a block diagram showing a SIP product including a memory chip and a logic chip, which are mutually combined, in a semiconductor device according to a first embodiment of the present invention. A memory chip 10 includes a multi-bit, for example a memory circuit 11 including a general memory such as a DRAM, and a test circuit 12 for making a memory test. The test circuit 12 has the following two functions. For example, one is a test function of testing the memory circuit 11. Another is a test function (module burn-in and operation speed test) of testing normal pass from a logic chip 20 to the memory chip 10. The memory circuit 11 and the test circuit 12 included in the memory chip 10 are connected in the memory chip 10. The logic chip 20 is provided with an internal logic circuit (Logic) 21.

As shown in FIG. 2, the memory chip 10 is stacked on the center portion of the logic chip 20. A plurality of pads of both chips is electrically connected using many bonding wires 22.

If the memory circuit 11 of the memory chip 10 is tested using the test circuit 12, basically, a connection path between the memory circuit 11 formed in the memory chip 10 and the test circuit 12 is used to make a test.

Conversely, memory access from the logic chip 20 to the memory chip 10 is tested after a device is assembled as a SIP product. In this case, signal exchange is made between the test circuit 12 and the logic chip 20 via many bonding wires connected between both chips. Finally, the connection path between the memory circuit 11 and the test circuit 12 is used to make a test.

An input/output signal when both chips are tested is supplied to a pad of the memory chip 10. In the test of the memory circuit 11 of the memory chip 10, the test circuit 12 is used to confirm basic test items of the memory circuit 11, for example, operation margin and function. In the memory access test from the logic chip 20 after the SIP product is assembled, the test circuit 12 is used to confirm test items (memory operation speed test including access pass, module burn-in), which are not tested by a single test item of the memory circuit 11.

As described above, a test circuit required for testing the memory circuit is the test circuit 12 only built in the memory chip 10. The logic chip 20 is not provided with a test circuit for an inherently unnecessary memory test. Therefore, design efficiency of the logic chip 20 is improved.

### Second Embodiment

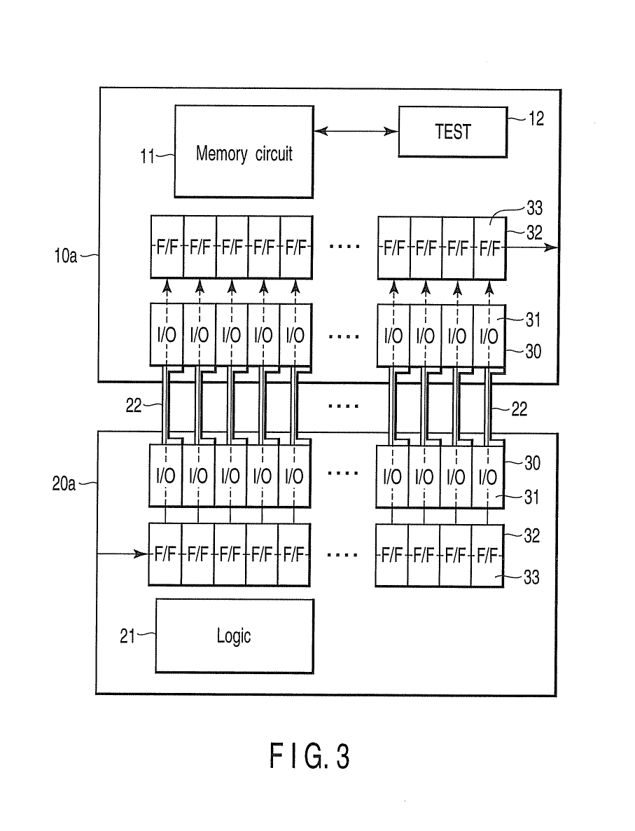

FIG. 3 is a block diagram showing a SIP product including a memory chip and a logic chip, which are mutually combined, in a semiconductor device according to a second embodiment of the present invention. In the SIP product of the second embodiment, a memory chip 10a and a logic chip 20a are electrically connected using 128 bonding wires 22, for example. Both memory chip 10a and logic chip 20a are formed with an I/O cell column 30 including 128 I/O cells corresponding to the foregoing 128 bonding wires 22. Both memory chip 10a and logic chip 20a are further provided with a flip-flop circuit column including 128 boundary scan test flip-flop circuits (F/F circuit) 33. Each I/O cell 31 of the I/O cell column 30 is connected to the corresponding flip-flop circuit 33 of the flip-flop circuit column 32. Each corresponding flip-flop circuit 33 of the flip-flop circuit column 32 is connected to the same clock signal source. A test circuit 12 provided in the memory chip 10a has the following two functions. One is a test function of testing a memory circuit 11. Another is a test function with data exchange between the memory chip 10a and the logic chip 20a.

Like FIG. 2, the memory chip 10a is stacked on the center portion of the logic chip 20a. A plurality of pads of both chips is electrically connected using many bonding wires 22.

In the SIP product shown in FIG. 3, the memory circuit 11 of the memory chip 10a is tested using the test circuit 12. In this case, basically, a connection path between the memory circuit 11 and the test circuit 12 formed in the memory chip 10a is used to make a test.

On the other hand, memory access from the logic chip 20a to the memory chip 10a is tested after the device is assembled as a SIP product. In this case, a signal exchange is made between the test circuit 12 and the logic chip 20a via a plurality of bonding wires connected between both chips. Finally, the connection path between the memory circuit 11 and the test circuit 12 is used to make a test.

A connection test of a signal sent from the logic chip 20a to the memory chip 10a is made. In this case, logic data is serially input to the flip-flop circuit column 32 of the logic chip 20a from the outside. Data is input all of flip-flop circuits 33 of the flip-flop circuit column 32. Thereafter, data input/output is made in parallel between the flip-flop circuit column 32 and the I/O cell column 30, and then, a clock signal is once input. In this case, data input to the flip-flop circuit column 32 of the logic chip 20a is transferred to the flip-flop circuit column 32 of the memory chip 10a via the I/O cell 31 of the I/O cell column 30 and the bonding wires 22. Thereafter, data is serially output from the flip-flop circuit column 32 of the memory chip 10a. As a result, if no failure occurs, data input to the flip-flop circuit column 32 of the logic chip 20a coincides with data output from the flip-flop circuit column 32 of the memory chip 10a. Conversely, if different data exists, failure occurs in the I/O cell 31 connected to the flip-flop circuit 33 of the flip-flop circuit column 32 and/or bonding wire 22. Thus, when a test is made, a failure portion is specified. The same operation as above is carried out when a connection test sent from the memory chip 10a to the logic chip 20a is made.

### Third Embodiment

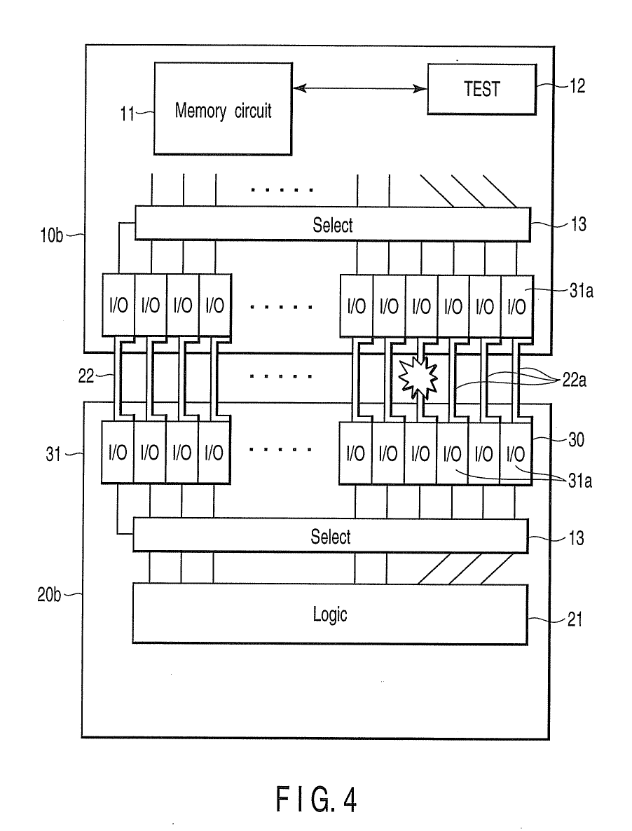

FIG. 4 is a block diagram showing a SIP product including a memory chip and a logic chip, which are mutually combined, in a semiconductor device according to a third embodiment of the present invention. In the SIP product shown in FIG. 3, failure redundancy circuit is shown when a failure portion is specified. For simplification of explanation, illustration of the flip-flop circuit column 32 shown in FIG. 3 is omitted. Like FIG. 3, both memory chip 10b and logic chip 20b are provided with an I/O cell column 30 including a plurality of I/O cells 31.

The SIP product of the third embodiment further has the following configuration. The I/O cell column 30 provided in both memory chip 10b and logic chip 20b includes a plurality of normal input/output cells 31 and spare many input/output cells 31a. The bonding wires 22 includes normal many bonding wires 22 and spare many bonding wires 22a for mutually connecting the spare many input/output cells 31a each other. In each of the chip 10b and 20b, a select circuit 13 is additionally connected in a connection path between I/O cell 31, 31a and internal circuits.

In the SIP product shown in FIG. 4, the test described in the second embodiment is made under the control by the test circuit 12. As a result, if failure is detected from a certain bonding wire 22, the following operation is made. Specifically, of the I/O cell column 30, usable I/O cell 31, 31a after the I/O cell corresponding to the failure bonding wire 22 and the corresponding bonding wires 22 and 22a are all shifted by one bit using the select circuit 13. In this way, after the SIP product is assembled, failure redundancy of the I/O cell and/or bonding wire is made; therefore, the yield of the SIP product is improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device having a system in package structure, comprising:
a memory chip having a memory circuit, and including a test circuit for making an operation test of the memory chip itself; and
an integrated circuit chip electrically connected with the memory chip.

2. The device according to claim 1, wherein the memory circuit is a DRAM circuit.

3. The device according to claim 1, wherein the integrated circuit chip includes a logic circuit.

4. The device according to claim 1, wherein the memory chip is stacked on the integrated circuit chip.

5. The device according to claim 1, wherein the test circuit has a test function with a data exchange between the memory chip and the integrated circuit chip.

6. The device according to claim 5, wherein the memory chip and the integrated circuit chip each have a plurality of input/output cells, and the memory chip and the integrated circuit chip are electrically connected via a plurality of bonding wires.

7. The device according to claim 6, wherein each of the memory chip and the integrated circuit chip further includes a plurality of flip-flop circuits connected to said plurality of input/output cells,
the test circuit has a test function of making a boundary scan test using said plurality of flip-flop circuits of the memory chip and the integrated circuit chip.

8. The device according to claim 6, wherein the test circuit has a test function of making a detection whether or not failure exists in each input/output cell of the memory chip and the integrated circuit chip and/or said plurality of bonding wires.

9. The device according to claim 7, wherein said plurality of input/output cells of the memory chip and the integrated circuit chip includes a plurality of normal input/output cells and a plurality of spare input/output cells,
said plurality of bonding wires includes a plurality of normal bonding wires and a plurality of spare bonding wires mutually connecting the spare input/output cells,
each of the memory chip and the integrated circuit chip further includes a control circuit shifting a connection path in which the spare input/output cell is used in place of the normal input/output cell.

10. A method of testing a semiconductor device assembled as a system in package product including a memory chip and an integrated circuit chip each having a plurality of input/output cells, which are electrically connected via a plurality of bonding wires, comprising:
making a test of the memory chip to make a detection whether or not failure exists in each input/output cell of the memory chip and the integrated circuit chip and/or said plurality of bonding wires.

11. The method according to claim 10, wherein the memory circuit is a DRAM circuit.

12. The method according to claim 10, wherein the integrated circuit chip includes a logic circuit.

13. The method according to claim 10, wherein the memory chip is stacked on the integrated circuit chip.

14. A method of testing a semiconductor device assembled as a system in package product including a memory chip and an integrated circuit chip each having a plurality of input/output cells,
said plurality of input/output cells including a plurality of normal input/output cells and a plurality of spare input/output cells, and
said plurality of bonding wires including a plurality of normal bonding wires and a plurality of spare bonding wires mutually connecting the spare input/output cells, comprising:
making a test of the memory chip to make a detection whether or not failure exists in each input/output cell of the memory chip and the integrated circuit chip and/or said plurality of bonding wires; and
shifting a connection path in replacement with the spare bonding wire and the spare input/output cell to make failure redundancy of the input/output cell and/or the bonding wire when failure is detected in any of the input/output cell on each chip or the bonding wire according to the test.

15. The method according to claim 14, wherein the memory circuit is a DRAM circuit.

16. The method according to claim 14, wherein the integrated circuit chip includes a logic circuit.

17. The method according to claim 14, wherein the memory chip is stacked on the integrated circuit chip.
